(19) United States
(12) Patent Application Publication
(10) Pub. No.: US 2016/0203950 A1
(43) Pub. Date: Jul. 14, 2016

(54) METHOD AND ION IMPLANTER FOR LOW TEMPERATURE IMPLANTATION

(71) Applicant: ADVANCED ION BEAM TECHNOLOGY, INC., Hsinchu (TW)

(72) Inventors: Anwar HUSAIN, Pleasanton, CA (US); Tzuyuan YIIN, Fremont, CA (US); Tienyu SHENG, Saratoga, CA (US)

(21) Appl. No.: 14/595,813

(22) Filed: Jan. 13, 2015

(51) Int. Cl. H01J 37/317; C23C 14/48; H01J 37/244; G01K 7/22; H01J 37/20

(52) U.S. Cl. CPC H01J 37/3171; G01K 7/22; H01J 37/20; H01J 37/244; C23C 14/48; H01J 2237/31701; H01J 2237/202; H01J 2237/2001

(57) ABSTRACT

A method for a recipe of a low temperature implantation comprises: pre-cooling a workpiece transferred from a FOUP to a lower temperature to meet the recipe, implanting the workpiece according to the recipe, and post-heating the workpiece to a higher temperature before returning the workpiece to the FOUP. Further, an ion implanter comprising a process chamber, a FOUP, a cooling module and a heating module is provided. The workpiece can be implanted according to the recipe in the process chamber. The FOUP can transfer the workpiece toward and away from the process chamber. The cooling module is disposed outside the process chamber and can pre-cool the workpiece to the lower temperature to meet the recipe before implanting the workpiece. The heating module is disposed outside the process chamber and can post-heat the workpiece to the higher temperature before returning the workpiece to the FOUP.

### FIELD OF THE INVENTION

The present invention generally relates to a method and an ion implanter for an ion implantation, and more particularly to a method and an ion implanter for a low temperature implantation.

### DESCRIPTION OF THE RELATED ART

Ion implantation is a very important technique for the manufacture of semiconductors, such as integrated circuit (IC), memory, flat plan display (FPD), solar cell and so on, which is used to dope impurities into a workpiece, such as a silicon wafer, a glass plate and so on, with an ion implanter. In addition, the accuracy of performing the ion implantation significantly influences on yielding rate of the manufacture. However, most of the researches of the ion implantation focus on ways to scan a workpiece instead of the temperature control before and after scanning the workpiece.

For example, in some specific cases, cooling a workpiece before it is implanted may increase the total accuracy of performing the ion implantation. However, the conventional ion implanters are usually designed without any cooler for previously cooling the workpiece to meet a recipe of a low temperature implantation. Furthermore, the temperature of the workpiece is increased during the ions provided by an ion implanter continuously impinging onto the workpiece. However, high temperature of the workpiece is possible to decrease the accuracy of the later process. Also, in order to maintain the accuracy of the later process, a common approach is cooling the workpiece while the ion implantation process is performed. However, with the structure of the semiconductors becoming more complicated, the possible of the workpiece being over heated during the ion implantation process is increased. As a result, it is desired to provide a new ion implanter and/or implantation method for the low temperature implantation to prevent the workpiece from being over heated.

### SUMMARY OF THE INVENTION

The present invention is directed to a method for a low temperature implantation and an ion implanter thereof, wherein a workpiece can be pre-cooled to meet a recipe of the low temperature implantation and post-heated before being returned to the FOUP (front opening unified pod) to prevent the moisture in the atmosphere from condensing onto the wafer.

The present invention provides a method for a low temperature implantation, which comprises the following steps. First, a workpiece is pre-cooled to a first temperature to meet a recipe of the low temperature implantation. Next, the workpiece is implanted according to the recipe. Afterward, the workpiece is post-heated to a second temperature higher than the first temperature in a load lock before being returned to a FOUP.

According to an embodiment of the present invention, the first temperature is significantly lower than a room temperature, while the second temperature is equal to or higher than a dew point at the moment starting to pass the workpiece from a vacuum condition to an ambient condition.

According to an embodiment of the present invention, the first temperature is equal to or lower than −40° C.

According to an embodiment of the present invention, the step for pre-cooling the workpiece comprises chilling an ESC (electro static chuck) by a chiller via a coolant line connected therebetween before transferring the workpiece to a process chamber for the recipe.

According to an embodiment of the present invention, the step for pre-cooling the workpiece is treated in a cooling chamber communicating with a process chamber for the recipe.

According to an embodiment of the present invention, the step for post-heating the workpiece comprises warming the workpiece by at least a lamp disposed outside a process chamber for the recipe.

The present invention also provides an ion implanter comprising a process chamber, a FOUP, a load lock, a cooling module and a heating module. A workpiece is capable of being implanted according to a recipe of a low temperature implantation in the process chamber. The FOUP is capable of transferring a workpiece toward and away from the process chamber. The load lock is located between the process chamber and the FOUP. The cooling module is disposed in or outside the process chamber and capable of pre-cooling the workpiece to a first temperature to meet the recipe before implanting the workpiece. The heating module is disposed in the load lock and capable of post-heating the workpiece to a second temperature higher than the first temperature before returning the workpiece to the FOUP.

According to an embodiment of the present invention, the cooling module comprises a cooling chamber, an ESC, a chiller and a coolant line. The cooling chamber communicates with the process chamber. The ESC is disposed in the cooling chamber for holding the workpiece. The chiller is disposed outside the cooling chamber. The coolant line connects the ESC to the chiller, so as to chill the ESC by the chiller via the coolant line. According to a specific embodiment, the cooling module can further comprise a thermistor disposed on the ESC for monitoring a temperature of the ESC. According to another specific embodiment, the cooling module can also comprise a sensor disposed in the cooling chamber for detecting a position of the workpiece or monitor presence of the workpiece.

According to an embodiment of the present invention, the heating module is integrated in a lid of the load lock. According to a specific embodiment, the heating module can comprise a housing, a quartz window and at least a lamp, wherein the quartz window covers the housing to form the lid, and the lamp is installed between the housing and the quartz window. According to another specific embodiment, the heating module further comprises a reflector located on an inner surface of the housing.

The present invention further provides a method for a low temperature implantation, which comprises the following steps. First, an ESC is chilled by a chiller via a coolant line connected between the ESC and the chiller, so as to pre-cool a workpiece to a first temperature to meet a recipe of the low temperature implantation. Next, the workpiece is transferred to a process chamber for the recipe. Afterward, the workpiece is implanted according to the recipe in the process chamber. Then, the workpiece is warmed in a load lock by at least a heating device disposed outside the process chamber, so as to post-heat the workpiece to a second temperature higher than the first temperature. Later, the workpiece is returned to a FOUP.

According to an embodiment of the present invention, the first temperature is significantly lower than a room temperature, while the second temperature is equal to or higher than a dew point at the moment starting to pass the workpiece from a vacuum condition to an ambient condition.

According to an embodiment of the present invention, the first temperature is equal to or lower than −40° C.

According to an embodiment of the present invention, the step for pre-cooling the workpiece is treated in a cooling chamber communicating with the process chamber.

According to an embodiment of the present invention, the heating device is a lamp or a heating wire.

Accordingly, a workpiece can be pre-cooled to meet the recipe of the low temperature implantation and post-heated before being returned to the FOUP to prevent the moisture in the atmosphere from condensing onto the wafer by using the present invention.

### BRIEF DESCRIPTION OF THE DRAWINGS

FIG. 1 illustrates a flow chart of a low temperature implantation according to an embodiment of the present invention.

FIG. 2 illustrates a schematic view of an ion implanter according to an embodiment of the present invention.

FIG. 3 illustrates a cross-sectional view of the cooling module as shown in FIG. 2.

FIG. 4 illustrates a cross-sectional view of the second load lock as shown in FIG. 2.

### DETAILED DESCRIPTION OF THE INVENTION

Reference will now be made in detail to specific embodiments of the present invention. Examples of these embodiments are illustrated in the accompanying drawings. While the invention will be described in conjunction with these specific embodiments, it will be understood that it is not intended to limit the invention to these embodiments. In fact, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations are not described in detail in order not to obscure the present invention. Besides, in all of the following embodiments, the same or similar components illustrated in different embodiments refer to the same symbols.

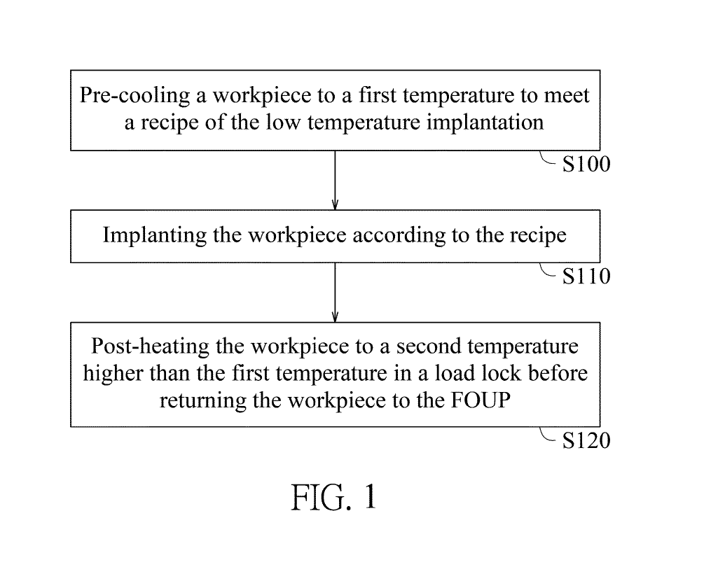

FIG. 1 illustrates a flow chart of a low temperature implantation method according to an embodiment of the present invention. Referring to FIG. 1 first, the method according to the present embodiment comprises the following steps. First, as shown in a block S100, a workpiece, for example but not limited to a silicon wafer, a glass plate and so on, is pre-cooled to a first temperature to meet a required temperature of a recipe of the low temperature implantation. In an embodiment, the workpiece can be transferred from a FOUP to a first load lock first, so as to pass the workpiece from an ambient condition to a vacuum condition. Next, the workpiece can further be transferred to a cooling chamber in the vacuum condition, so as to treat the step for pre-cooling the workpiece in the cooling chamber. For example, the step for pre-cooling the workpiece can be practiced by chilling an ESC with a chiller via a coolant line connected between the ESC and the chiller, wherein the ESC is used for holding and transferring the workpiece. In addition, in a preferred embodiment, the first temperature can be significantly lower than a room temperature, and preferably equal to or lower than −40° C.

Next, as shown in a block S110, the workpiece is transferred to a process chamber for being implanted according to the recipe. Then, as shown in a block S120, the workpiece is post-heated to a second temperature higher than the first temperature in a second load lock first, and then returned to the FOUP. In an embodiment, the workpiece can be transferred from the process chamber to the second load lock in the vacuum condition first after the low temperature implantation is finished. Next, the workpiece can be post-heated in the second load lock during the workpiece is passed from a vacuum condition to an ambient condition in the second load lock. In an embodiment, the step for post-heating the workpiece can be treated by warming the workpiece with at least a heating device disposed in the second load lock, wherein the heating device in the following embodiments can be exemplarily illustrated as a lamp, for example an IR lamp, but can further be a conventional heating wire in another non-illustrated embodiment as well. Besides, in a preferred embodiment, all of the first load lock, the second load lock, the cooling chamber and the process chamber can communicate with each other via a VTM (vacuum transfer module) chamber. Furthermore, in a preferred embodiment, in order to prevent the moisture in the atmosphere from condensing onto the workpiece, the second temperature should be equal to or higher than the room temperature, and preferably equal to or higher than a dew point at the moment starting to pass the workpiece from a vacuum condition to an ambient condition.

As a result, in the present invention, since the workpiece is pre-cooled, it is possible to not only implant the workpiece according to a recipe of a low temperature implantation but also prevent the workpiece from being overheated during the ions continuously impinging the workpiece. Besides, since the workpiece is post-heated, it is further possible to prevent the moisture in the atmosphere from condensing onto the workpiece. Further, it is also possible to modify the conventional ion implantation procedure for improving the yielding rate of the manufacture by pre-cooling a workpiece at least one time and/or post-heating a workpiece at least one time. For helping a person having ordinary skilled in the art to well understand the low temperature implantation methods described herein, the disclosure further illustrates an ion implanter capable of being used for the low temperature implantation method hereinafter. However, the low temperature implantation method(s) should not be limited to the usage(s) of the following ion implanter.

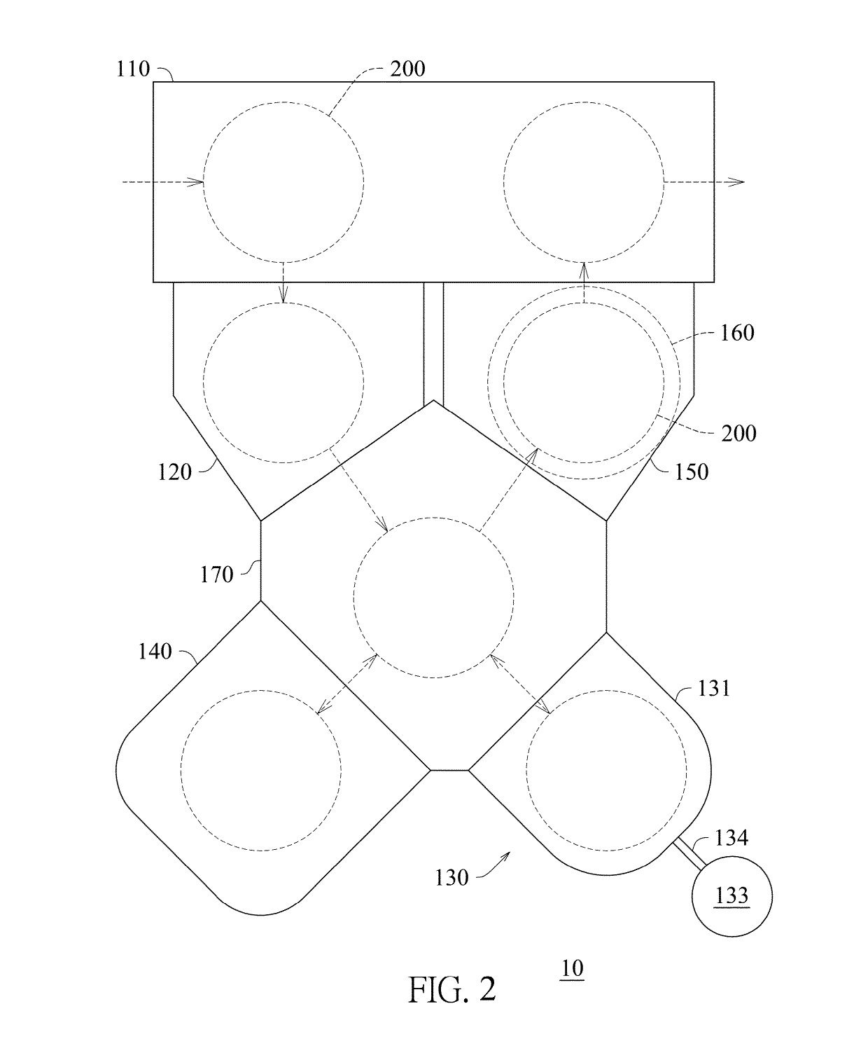

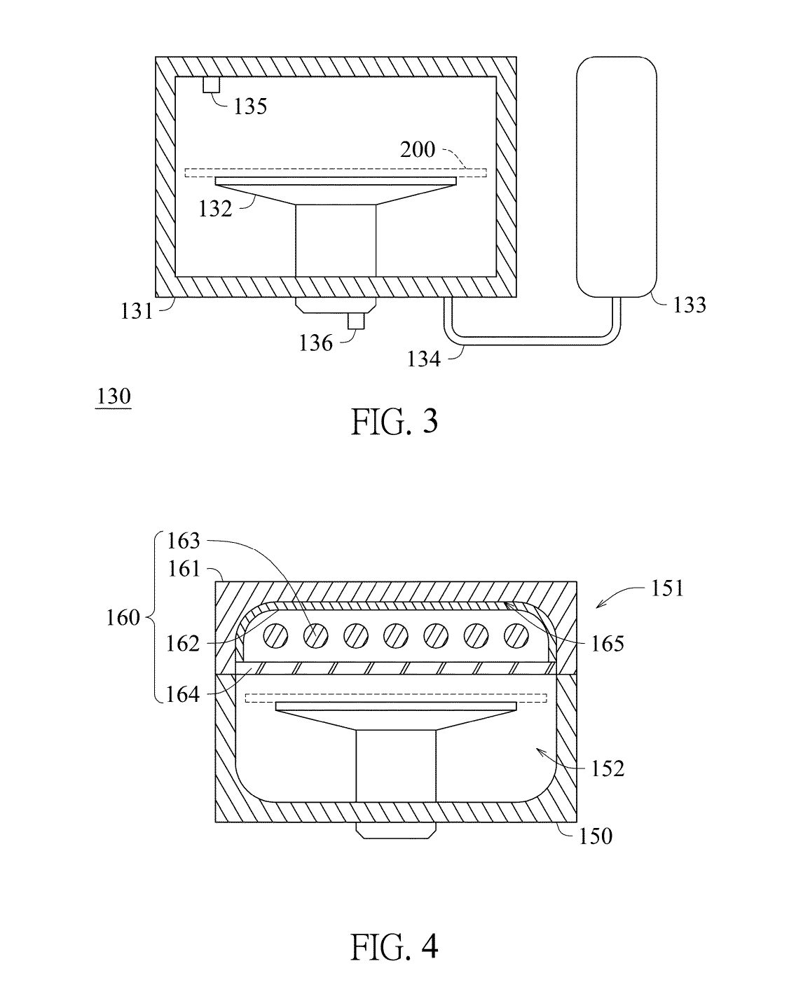

FIG. 2 illustrates a schematic view of an ion implanter according to an embodiment of the present invention, while FIGS. 3 and 4 respectively illustrate a cross-sectional view of the cooling module and the second load lock as shown in FIG. 2. Referring to FIGS. 2-4, the ion implanter 100 comprises a FOUP 110, a first load lock 120, a cooling module 130, a process chamber 140, a second load lock 150, a heating module 160 and a VTM chamber 170. The FOUP 110 is used for transferring a workpiece 200 toward and away from the process chamber 140. The first load lock 120 is located between the FOUP 110 and the process chamber 140, and used for passing the workpiece 200 from an ambient condition to a vacuum condition. The cooling module 130 is disposed outside the process chamber 140, and preferably located between the first load lock 120 and the process chamber 140, so as to enable the workpiece 200 to be pre-cooled before being implanted according to a recipe of a low temperature implantation in the process chamber 140. The second load lock 150 is located between the process chamber 140 and the FOUP 110, and used for passing the workpiece 200 from the vacuum condition to the ambient condition. Further, the heating module 160 is disposed to the first load lock 120 or the second load lock 150 or both, and preferably integrated with a lid 151, so as to enable the workpiece 200 to be post-heated before being returned to the FOUP 110. Moreover, all of the first load lock 120, a cooling chamber 131 of the cooling module 130, the process chamber 140 and the second load lock 150 can communicate with each other via the VTM chamber 170, so as to enable the workpiece 200 to be transferred therebetween in the vacuum condition.

Accordingly, the workpiece 200 transferred from the FOUP 110 can be treated with the low temperature implantation by sequentially being passed to the vacuum condition in the first load lock 120, pre-cooled to a first temperature to meet a required temperature of the recipe in the cooling module 130, implanted according to the recipe in the process chamber 140, post-heated to a second temperature higher than the first temperature by the heating module 160 during the workpiece 200 is passed to the ambient condition in the second load lock 150 and returned to the FOUP 120.

In detail, referring to FIG. 3, in the present preferred embodiment, the cooling module 130 can be composed of a cooling chamber 131, an ESC 132, a chiller 133 and a coolant line 134. The cooling chamber 131 communicating with the process chamber 140, while the ESC 132 is disposed in the cooling chamber 131 for holding the workpiece 200. In addition, the chiller 133 is disposed outside the cooling chamber 131, and the coolant line 134 connects the ESC 132 to the chiller 133, so as to chill the ESC 132 by the chiller 133 via the coolant line 134. As a result, as long as a sensor 135 disposed in the cooling chamber 131 monitors that a workpiece 200 is presented in the cooling chamber 131 and/or detects that a workpiece 200 is moved to a predetermined position, the chiller 133 can be activated to send a coolant, such as refrigerant, liquid nitrogen and so on, to the ESC 132 via the coolant line 134 for rapidly cooling the workpiece 200 held by the ESC 132 until the ESC 132 is monitored achieving the first temperature by a thermistor 136 disposed on the ESC 132.

In contrast, referring to FIG. 4, the heating module 160 can be composed of a housing 161, a reflector 162, at least a lamp 163 and a quartz window 164. The housing 161 is formed from the lid 151 of the second load lock 150, while the reflector 162 is formed on an inner surface 165 of the housing 161 for heating the workpiece 200 more uniformly. The lamp 163 is installed inside the housing 161, while the quartz window 164 covers the housing 161, so as to separate the lamp 163 from a vacuum zone 152 of the second load lock 150 and form the lid 151 with the housing 161. As a result, after a workpiece 200 is transferred into the vacuum zone 152, the lamp 163 can be activated, so as to warm up the workpiece 200 to the second temperature.

In summary, by using the above-mentioned method(s) and/or ion implanter(s) for a low temperature implantation disclosed in the present disclosure, it is possible to achieve at least one of the following advantages, comprising but not limited to: implanting a workpiece according to a recipe of a low temperature implantation, preventing a workpiece from being overheated during the ions continuously impinging the workpiece, preventing the moisture in the atmosphere from condensing on a workpiece, modifying a conventional ion implantation procedure for improving the yielding rate of the manufacture by pre-cooling a workpiece at least one time and/or post-heating a workpiece at least one time, and so on.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for a low temperature implantation, comprising:
pre-cooling a workpiece to a first temperature to meet a recipe of the low temperature implantation;
implanting the workpiece according to the recipe; and
post-heating the workpiece in a load lock to a second temperature higher than the first temperature before being returned to a FOUP.

2. The method as claimed in claim 1, wherein the first temperature is significantly lower than a room temperature, while the second temperature is equal to or higher than a dew point at the moment starting to pass the workpiece from a vacuum condition to an ambient condition.

3. The method as claimed in claim 2, wherein the first temperature is equal to or lower than −40° C.

4. The method as claimed in claim 1, wherein the step for pre-cooling the workpiece comprises chilling an ESC by a chiller via a coolant line connected therebetween before transferring the workpiece to a process chamber for the recipe.

5. The method as claimed in claim 1, wherein the step for pre-cooling the workpiece is treated in a cooling chamber communicating with a process chamber for the recipe.

6. The method as claimed in claim 1, wherein the step for post-heating the workpiece comprises warming the workpiece by at least a lamp disposed outside a process chamber for the recipe.

7. An ion implanter, comprising:
a process chamber, wherein a workpiece is capable of being implanted according to a recipe of a low temperature implantation therein;
a FOUP, capable of transferring a workpiece toward and away from the process chamber;
a load lock, located between the process chamber and the FOUP;
a cooling module, capable of pre-cooling the workpiece to a first temperature to meet the recipe before implanting the workpiece; and
a heating module, disposed in the load lock and capable of post-heating the workpiece to a second temperature higher than the first temperature before returning the workpiece to the FOUP.

8. The ion implanter as claimed in claim 7, wherein the cooling module comprises:
a cooling chamber, communicating with the process chamber;
an ESC, disposed in the cooling chamber for holding the workpiece;
a chiller, disposed outside the cooling chamber; and
a coolant line, connecting the ESC to the chiller, so as to chill the ESC by the chiller via the coolant line.

9. The ion implanter as claimed in claim 8, wherein the cooling module further comprises a thermistor disposed on the ESC for monitoring a temperature of the ESC.

10. The ion implanter as claimed in claim 8, wherein the cooling module further comprises a sensor disposed in the cooling chamber for detecting a position of the workpiece.

11. The ion implanter as claimed in claim 8, wherein the cooling module further comprises a sensor disposed in the cooling chamber for monitor presence of the workpiece.

12. The ion implanter as claimed in claim 7, wherein the heating module is integrated in a lid of the load lock.

13. The ion implanter as claimed in claim 12, wherein the heating module comprises:
a housing;
a quartz window, covering the housing to form the lid; and
at least a lamp, installed between the housing and the quartz window.

14. The ion implanter as claimed in claim 13, wherein the heating module further comprises a reflector located on an inner surface of the housing.

15. A method for a low temperature implantation, comprising:
chilling an ESC by a chiller via a coolant line connected between the ESC and the chiller, so as to pre-cool a workpiece to a first temperature to meet a recipe of the low temperature implantation;
transferring the workpiece to a process chamber for the recipe;
implanting the workpiece according to the recipe in the process chamber;
warming the workpiece in a load lock by at least a heating device disposed outside the process chamber, so as to post-heat the workpiece to a second temperature higher than the first temperature; and
returning the workpiece to a FOUP.

16. The method as claimed in claim 15, wherein the first temperature is significantly lower than a room temperature, while the second temperature is equal to or higher than a dew point at the moment starting to pass the workpiece from a vacuum condition to an ambient condition.

17. The method as claimed in claim 15, wherein the first temperature is equal to or lower than −40° C.

18. The method as claimed in claim 15, wherein the step for pre-cooling the workpiece is treated in a cooling chamber communicating with the process chamber.

19. The method as claimed in claim 15, wherein the heating device is a lamp or a heating wire.
